(19) United States
(12) Patent Application Publication
(10) Pub. No.: US 2025/0341786 A1
(43) Pub. Date: Nov. 6, 2025

(54) CONTOUR EXTRACTION MODEL LEARNING DEVICE AND METHOD FOR DETECTING CONTOUR OF SEMICONDUCTOR LITHOGRAPHY PATTERN

(71) Applicant: SEOUL NATIONAL UNIVERSITY R&DB FOUNDATION, Seoul (KR)

(72) Inventors: Do-Nyun KIM, Seoul (KR); Tae-Yeon KIM, Seoul (KR)

(21) Appl. No.: 19/219,623

(22) Filed: May 27, 2025

Related U.S. Application Data
(63) Continuation of application No. PCT/KR2025/099174, filed on Feb. 3, 2025.

(30) Foreign Application Priority Data
May 3, 2024 (KR) 10-2024-0058972

(51) Int. Cl. G03F 7/00

(52) U.S. Cl. CPC G03F 7/706839; G03F 7/70655

(57) ABSTRACT

A contour extraction model learning device for detecting a contour of a semiconductor lithography pattern includes a memory storing a contour extraction training program, and a processor configured to execute the contour extraction training program stored in the memory, wherein the contour extraction training program extracts a first contour image by inputting a SEM image of a new pattern to a contour extraction unit, generates a virtual SEM image by inputting the first contour image to a style transfer model, and trains the contour extraction model based on a training dataset in which the first contour image is matched with the virtual SEM image.

### CROSS-REFERENCE TO RELATED APPLICATION

This application is a continuation of International Patent Application No. PCT/KR2025/099174, filed on Feb. 3, 2025, which claims priority to Korean Patent Application No. 10-2024-0058972, filed on May 3, 2024, in the Korean Intellectual Property Office, the disclosure of which is incorporated by reference herein in its entirety.

### BACKGROUND

The present disclosure relates to a contour extraction model learning device and method for detecting a contour of a semiconductor lithography pattern.

Lithography is an important step of a semiconductor manufacturing process, and is a process of manufacturing a semiconductor device by using photoresist. The transistor integration is determined by the wavelength of light, and recently, research has been conducted to generate precise patterns through ultrafine processes and extreme ultraviolet (EUV) processes.

However, defects still occur in lithography patterns, and semiconductor companies are trying to solve the problem of pattern defects. Hundreds to thousands of semiconductor chips are fabricated in a single wafer, and it is important to minimize a defect rate of the wafer and increase the yield. Therefore, it is necessary to analyze repetitive patterns to determine which process has a problem. To this end, the contour of a lithography pattern has to be accurately extracted.

A semiconductor inspection system provides a contour based on a scanning electron microscope (SEM) image, and measures a critical dimension (CD) value based on the contour. The current contour extraction algorithm reads pixel values of the SEM image, and extracts the contour when the pixel values exceed a threshold. However, because the contour is based on the pixel values of the SEM image, the contour is vulnerable to noise, and the contour extraction threshold value may change depending on manufacturing process conditions, which may result in different results.

Therefore, models using deep learning have been proposed in recent studies. Because the deep learning focuses on features as well as pixels by considering the surrounding circumstances, conditions of the SEM image may be flexibly processed. However, most deep learning models are built based on supervised learning, which has a disadvantage of requiring a significant amount of ground truth data to be labeled.

A related patent literature includes Korean Patent No. 10-2588888 (Title: DEVICE AND METHOD FOR DETECTING PATTERN CONTOUR INFORMATION OF SEMICONDUCTOR LAYOUT).

### SUMMARY

The present disclosure provides a contour extraction model learning device and method for detecting a contour of a new semiconductor lithography pattern without ground truth label data.

However, technical issues to be solved by the present embodiment are not limited to the technical issues described above, and there may be other technical issues.

According to an aspect of the present disclosure, a contour extraction model learning device for detecting a contour of a semiconductor lithography pattern includes a memory storing a contour extraction training program, and a processor configured to execute the contour extraction training program stored in the memory, wherein the contour extraction training program extracts a first contour image by inputting a SEM image of a new pattern to a contour extraction unit, generates a virtual SEM image by inputting the first contour image to a style transfer model, and trains the contour extraction model based on a training dataset in which the first contour image is matched with the virtual SEM image.

According to another aspect of the present disclosure, a contour extraction model learning method for detecting a contour of a semiconductor lithography pattern performed by a learning device includes extracting a first contour image by inputting a SEM image of a new pattern to a contour extraction unit, generating a virtual SEM image by inputting the first contour image to a style transfer model, and training the contour extraction model based on a training dataset in which the first contour image is matched with the virtual SEM image.

According to the present disclosure, a training dataset composed of a first contour image and a virtual SEM image as a pair is constructed by using a new pattern SEM image and a layout image corresponding thereto, and a contour extraction model may be trained based on the training dataset.

Also, by sharing the weights learned by the training dataset with the pre-trained contour extraction model, the pre-trained contour extraction model may extract a semiconductor lithography pattern without ground truth label data.

### BRIEF DESCRIPTION OF THE DRAWINGS

Embodiments of the inventive concept will be more clearly understood from the following detailed description taken in conjunction with the accompanying drawings in which:

FIG. 1 is a configuration diagram of a contour extraction model learning device according to an embodiment of the present disclosure;

FIG. 2 is a diagram illustrating a detailed module of a contour extraction model learning device according to an embodiment of the present disclosure;

FIG. 3 is a flowchart illustrating a contour extraction model training process according to an embodiment of the present disclosure;

FIG. 4 is a diagram illustrating a training process and an inference process of a contour extraction model, according to an embodiment of the present disclosure;

FIG. 5 is a diagram illustrating a contour extraction unit according to an embodiment of the present disclosure;

FIG. 6 is a diagram illustrating a style transfer model according to an embodiment of the present disclosure; and

FIG. 7 is a diagram illustrating a contour extraction model according to an embodiment of the present disclosure.

### DETAILED DESCRIPTION OF THE EMBODIMENTS

Hereinafter, embodiments of the present disclosure will be described in detail with reference to the attached drawings such that those skilled in the art to which the present disclosure belongs may easily practice the present disclosure. However, the present disclosure may be implemented in various different forms and is not limited to the embodiments described herein. In addition, in order to clearly describe the present disclosure in the drawings, parts that are not related to the description are omitted, and similar components are given similar reference numerals throughout the specification.

In the entire specification of the present disclosure, when a component is described to be “connected” to another component, this includes not only a case where the component is “directly connected” to another component but also a case where the component is “electrically connected” to another component with another element therebetween. In addition, when it is described that a portion “includes” a certain component, this means that the portion may further include another component without excluding another component unless otherwise stated.

In the present disclosure, a “portion” includes a unit realized by hardware, a unit realized by software, and a unit realized by using both. In addition, one unit may be realized by using two or more pieces of hardware, and two or more units may be realized by using one piece of hardware. Meanwhile, a “˜portion” is not limited to software or hardware, and a “˜portion” may be configured to be included in an addressable storage medium or may be configured to reproduce one or more processors. Therefore, in one example, “˜portion” refers to components, such as software components, object-oriented software components, class components, and task components, and includes processes, functions, properties, and procedures, subroutines, segments of program code, drivers, firmware, microcode, circuits, data, databases, data structures, tables, arrays, and variables. The functions provided within the components and “portions” may be combined into a smaller number of components and “portions” or may be further separated into additional components and “portions”. Additionally, components and “portions” may be implemented to regenerate one or more central processing units (CPUs) included in a device or security multimedia card.

A network refers to a connection structure that enables information exchange between respective nodes, such as terminals and servers, and includes a local area network (LAN), a wide area network (WAN), the Internet (WWW: word wide web), wired and wireless data communication networks, a telephone network, a wired and wireless television communication network, and so on. A wireless data communication network includes, for example, third generation (3G), fourth generation (4G), fifth generation (5G), third generation partnership project (3GPP), long term evolution (LTE), world Interoperability for microwave access (WIMAX), Wi-Fi, Bluetooth communication, infrared communication, ultrasonic communication, visible light communication (VLC), LiFi, and so on but is not limited thereto.

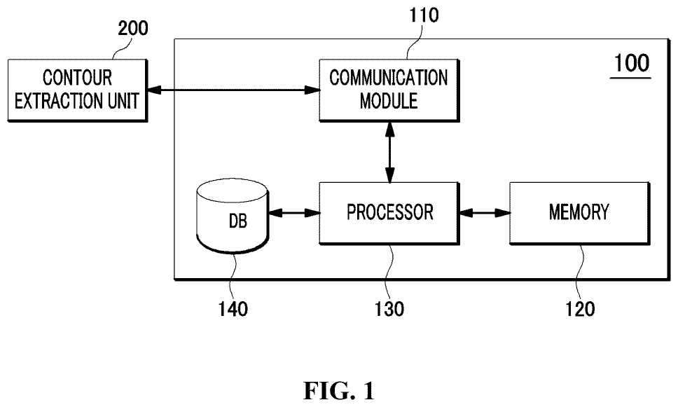

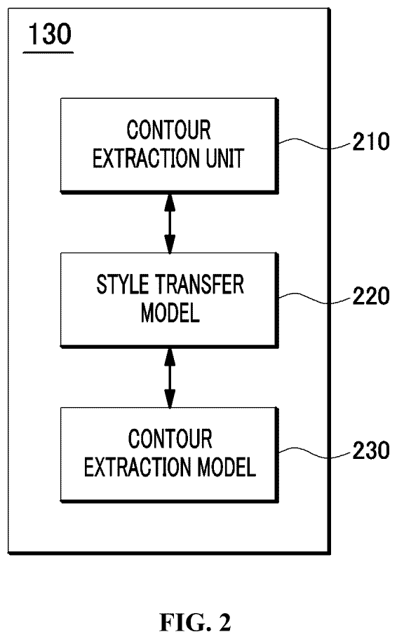

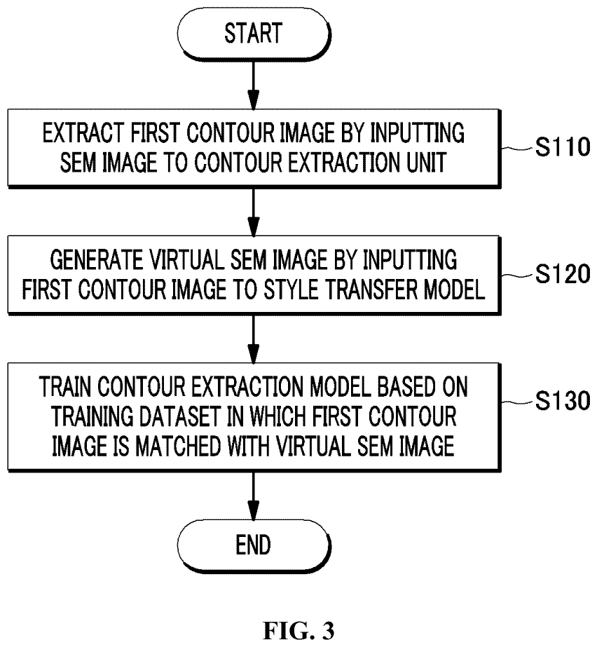

FIG. 1 is a configuration diagram of a contour extraction model learning device according to an embodiment of the present disclosure, FIG. 2 is a diagram illustrating a detailed module of the contour extraction model learning device according to the embodiment of the present disclosure, and FIG. 3 is a flowchart illustrating a contour extraction model training process according to an embodiment of the present disclosure.

Referring to FIG. 1, a contour extraction model learning device 100 may include a communication module 110, a memory 120, a processor 130, and a database 140.

The contour extraction model learning device 100 may be implemented by a computer or a mobile terminal that may be connected to a network. Here, the computer may include, for example, a desktop computer, a laptop computer, or so on, and the mobile terminal may be, for example, a wireless communication device that guarantees portability and mobility, and may include all kinds of handheld-based wireless communication devices, such as a smartphone, a tablet personal computer (PC), a smart watch, and so on.

In addition, the contour extraction model learning device 100 may function as a server that provides an external computing device with training results of a contour extraction model using a training dataset including a pair of a first contour image and a virtual scanning electron microscope (SEM) image. In this case, the server may include a cloud computing service model, such as software as a service (SaaS), platform as a service (PaaS), or infrastructure as a service (IaaS), or may be constructed in the form of a private cloud, a public cloud, or a hybrid cloud.

The communication module 110 may be a device including hardware and software required to transmit and receive signals, such as a control signals and a data signal through a wired or wireless connection with other network devices.

The memory 120 may be a device in which a contour extraction training program is recorded. The contour extraction training program includes operation S110 of extracting a first contour image by inputting a SEM image of a new pattern to a contour extraction unit 210, operation S120 of generating a virtual SEM image by inputting the first contour image to a style transfer model 220, and operation S130 of training a contour extraction model 230 based on a training dataset in which the first contour image is matched with the virtual SEM image. Here, the memory 120 may include a magnetic storage media or a flash storage media in addition to a volatile storage device that requires power to maintain the stored information, but the scope of the present disclosure is not limited thereto.

The memory 120 may store a separate program, such as an operating system for processing and controlling the processor 130, or may also perform a function for temporarily storing input or output data.

The processor 130 executes a contour extraction training program (hereinafter, a “program”) stored in the memory 120 and provides a function of controlling the hardware of the learning device 100 of the contour extraction model when the program is executed. That is, the processor 130 may perform hardware control functions of, for example, a file system, memory allocation, a network, a basic library, a timer, device control (display, media, input device, three-dimension (3D), or so on), and other utilities required by executing the program.

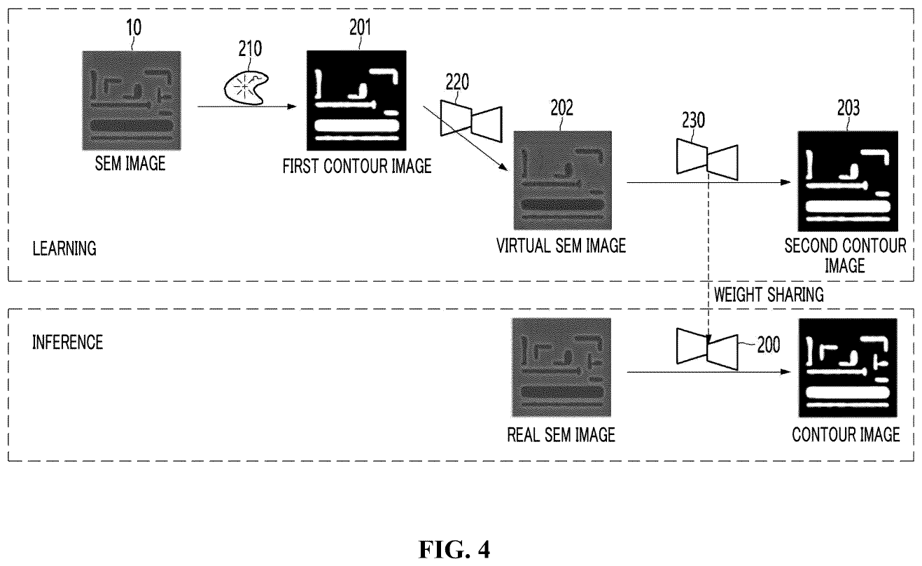

Referring to FIG. 2 and FIG. 3, the processor 130 includes operation S110 of extracting a first contour image by inputting a SEM image of a new pattern to a contour extraction unit 210, operation S120 of generating a virtual SEM image by inputting the first contour image to a style transfer model 220, and operation S130 of training a contour extraction model 230 based on a training dataset in which the first contour image is matched with the virtual SEM image. Also, specific steps of the contour extraction model training process according to the execution of the program are described below with reference to FIG. 4.

The processor 130 may include all kinds of devices that may process data. For example, the processor 130 may refer to a data processing device which includes a physically structured circuit to perform a function expressed by code or command included in the program and is built in hardware. The data processing device built in the hardware may include, for example, a microprocessor, a central processing unit (CPU), a processor core, a multiprocessor, an application-specific integrated circuit (ASIC), a field programmable gate array (FPGA), or so on, but the scope of the present disclosure is not limited thereto.

The database 140 stores or provides data required for the contour extraction model learning device 100 under the control by the processor 130. For example, the database 140 may store results generated during a contour extraction model training process. This database 140 may be included as a separate component from the memory 120, or may be built in a partial region of the memory 120.

Referring to FIG. 2, the processor 130 may include detailed modules that perform various functions according to the execution of a contour extraction training program. For example, the contour extraction training program may be executed by the processor 130 to implement the contour extraction unit 210, the style transfer model 220, and the contour extraction model 230.

FIG. 4 is a diagram illustrating a training process and inference process of a contour extraction model, according to an embodiment of the present disclosure.

Referring to FIG. 4, the contour extraction model learning device 100 according to the present disclosure may extract a first contour image 201 by inputting a SEM image 10 of a new pattern to the contour extraction unit 210 during the training process to (S110), and generate a virtual SEM image 202 by inputting the first contour image 201 to the style transfer model 220 (S120). Subsequently, the contour extraction model 230 may be trained based on a training dataset in which the first contour image 201 matches the virtual SEM image 202 Next, a weight learned by the training dataset may be shared with the pre-trained contour extraction model 200.

The pre-trained contour extraction model 200 has to be re-learned whenever a new lithography pattern appears. To do this, new ground truth data combined with a new pattern is required, and a process of generating the model gives a significant burden on semiconductor manufacturing facilities. However, the present disclosure reduces the need for data labeling, and may cause the contour extraction model 230 to be automatically trained in response to a change in lithography pattern of a semiconductor manufacturing facility, and may share the learned weight with the pre-trained contour extraction model 200.

Therefore, in the inference process, when a real SEM image of a new pattern is input, the pre-trained contour extraction model 200 may output a contour image from which the contour of a corresponding pattern is accurately detected.

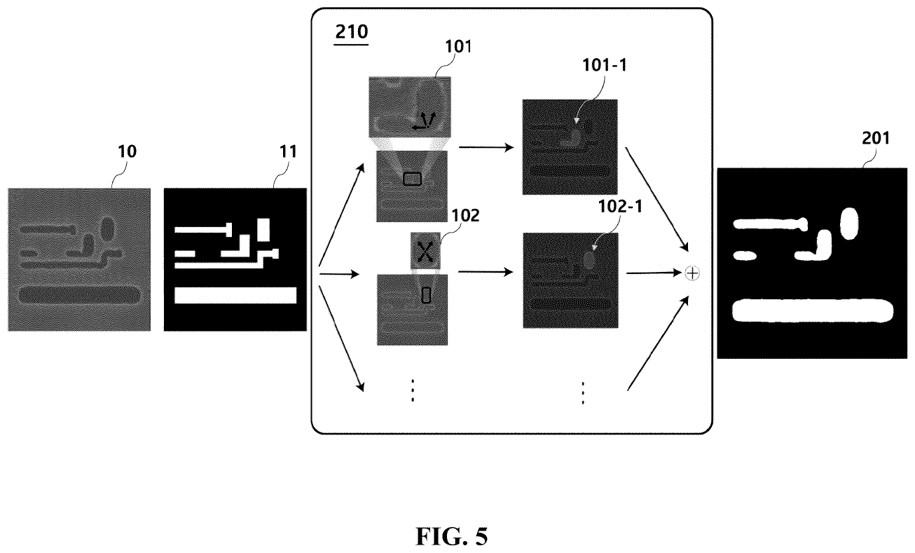

FIG. 5 is a diagram illustrating a contour extraction unit according to an embodiment of the present disclosure.

Referring to FIG. 5, the contour extraction unit 210 may obtain a layout image 11 corresponding to a SEM image 10, separate between a pattern region and a non-pattern region in the layout image 11, extract center coordinates of each pattern corresponding to the pattern region, determine a coordinate range within a preset number of pixels based on the center coordinates of each pattern in the SEM image 10 matched to the layout image 11 as contour extraction regions 101, 102, . . . , detect contours of patterns in the contour extraction regions 101, 102, . . . but stop the contour detection when the detected contours are out of the contour extraction regions 101, 102, . . . or when the detected contours exceed sizes of the pattern regions, and merge contours 101-1, 102-1, . . . of the patterns in the SEM image 10 to generate a first contour image 201.

For example, as illustrated in FIG. 5, the contour extraction unit 210 may determine coordinates within 25 pixels based on the center coordinates of each pattern detected from the layout image 11 and the center coordinates of each pattern in the SEM image 10 that matches the center coordinates, as the contour extraction regions 101, 102, . . . . Then, the contour extraction unit 210 may detect contours of patterns in contour extraction regions, stop the detection of contours when reaching a boundary (contour) of a pattern with a large pixel difference, and stop detection of contours in a certain instance when there is a risk of detection of a non-pattern region beyond the pattern region because the boundary of the pattern is ambiguous, or when the detected contour exceeds sizes of the separated pattern regions in the layout image 11.

In addition, the SEM image 10 has a pattern region and a non-pattern region, but the two regions often have similar pixel value distributions due to noise. Therefore, it is difficult to separate between a pattern region and a non-pattern region by binarizing the pixel values based on a threshold.

Therefore, the contour extraction unit 210 may more accurately detect contours from the SEM image 10 by using the layout image 11 and the SEM image 10 in which pattern regions and non-pattern regions are roughly separated.

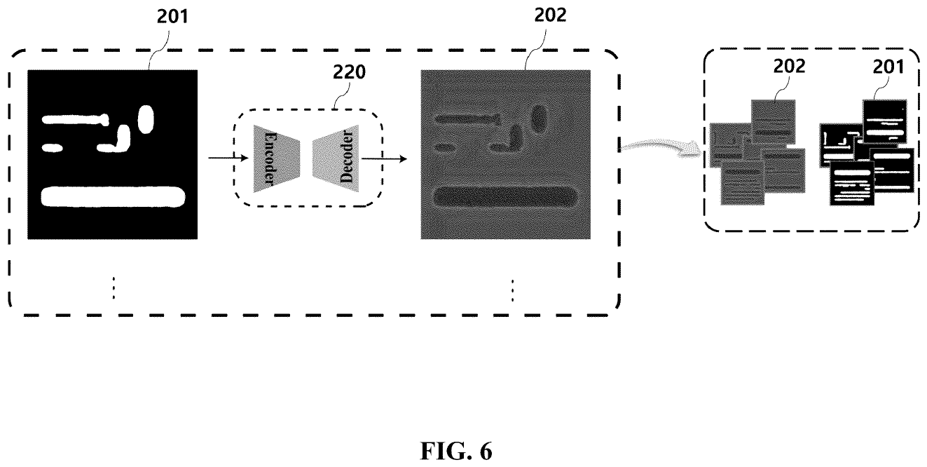

FIG. 6 is a diagram illustrating a style transfer model according to an embodiment of the present disclosure.

Referring to FIG. 6, the style transfer model 220 may be a model pre-trained by using a training dataset including a contour image and an SEM image matched thereto. Therefore, the style transfer model 220 may identify binarized pixel values in the input first contour image 201, detect a pattern region corresponding to the first pixel value and a non-pattern region corresponding to the second pixel value, and generate a virtual SEM image 202 having the pattern region and the non-pattern region which are converted.

For example, the style transfer model 220 may be implemented by one of the existing image transformation models. For example, a Pix2Pix model is an image transformation model based on a conditional generative adversarial network (CGAN), and may be trained by using an input image and an output image corresponding thereto as a pair.

That is, the style transfer model 220 may be composed of the Pix2Pix model, and may be trained by using a SEM image corresponding to a contour image by utilizing a structure of the CGAN. For example, the style transfer model 220 may generate the virtual SEM image 202 by converting a portion corresponding to 1 in the first contour image 201 into a pattern region and a portion corresponding to 0 into a non-pattern region regardless of an input contour.

In addition, the CGAN is trained by using two neural networks called a generator and a discriminator, and the generator receives an input image as an input and tries to generate a desired output image, and the discriminator tries to distinguish between an image generated by the generator and an actual output image. In this process, the generator is trained to generate an image that looks real, and the discriminator is trained to the extent that an output of the generator may not be distinguished from an actual image.

Referring again to FIG. 4 as an example, a program may generate the first contour image 201 for the SEM image 10 of a new pattern by the contour extraction unit 210, and generate the virtual SEM image 202 matching the first contour image 201 by the style transfer model 220.

Accordingly, the program may construct a training dataset in which the first contour image 201 matches the virtual SEM image 202 for the new pattern.

In this way, the present disclosure may construct a training dataset for a new lithography pattern without ground truth label data.

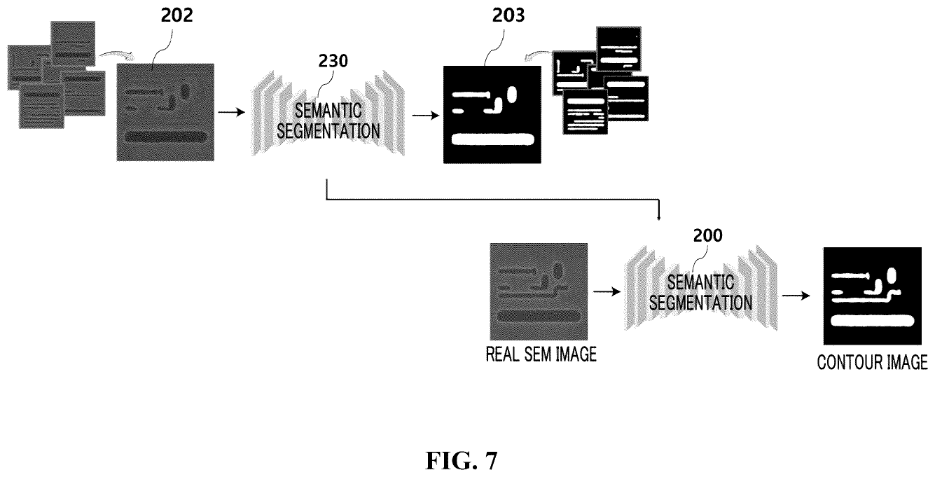

FIG. 7 is a diagram illustrating a contour extraction model according to an embodiment of the present disclosure.

The contour extraction model 230 is an auto-encoder model constructed based on a training dataset in which a first contour image 201 matches a virtual SEM image 202, and may include an encoder and a decoder. For example, the contour extraction model 230 may include a semantic segmentation model that segments an image into meaningful categories at a pixel level.

For example, the encoder may extract a first feature of each pattern from the input virtual SEM image 202. The decoder may extract a second feature of each pattern from a layout image corresponding to the virtual SEM image 202, generate a third feature of each pattern by combining the first feature of the virtual SEM image 202 with the second feature of the layout image, and generate a second contour image 203 based on the third feature of each pattern.

For example, the encoder may extract features of respective patterns from the virtual SEM image 202. For example, features of respective pattern contours may be extracted as a first feature based on an object feature extraction algorithm including a convolutional block attention module (CBAM) and an atrous spatial pyramid pooling (ASPP). The decoder may extract features of respective pattern contours as a second feature from a layout image (CAD image) corresponding to the virtual SEM image 202. Subsequently, the decoder may generate a third feature of each pattern contour by combining the first feature of each pattern contour extracted from the virtual SEM image 202 and the second feature of each pattern contour extracted from the layout image. Subsequently, the decoder may generate the third feature of each pattern contour as the second contour image 203 through a convolution layer, a batch normalization layer, a recited linear unit (ReLU) function, and up-sampling.

For reference, the contour extraction model 230 was disclosed in the prior patent (Korean Patent No. 10-2588888 (Title of the Invention: DEVICE AND METHOD FOR DETECTING PATTERN CONTOUR INFORMATION OF SEMICONDUCTOR LAYOUT)), and the contents of the prior patent may be referred to for more detailed information.

Referring again to FIG. 4 as an example, the program may cause the contour extraction

model 230 to be learned by using a training dataset constructed by a pair of the first contour image 201 and the virtual SEM image 202. In this case, the contour extraction model 230 has the same encoder and decoder structure as the pre-trained contour extraction model 200, and may be trained by the training dataset by using appropriate weights. In addition, the program may share, with the pre-trained contour extraction model 200, the weights of the encoder and decoder of the contour extraction model 230 whose learning is completed. In this case, the weights of the pre-trained contour extraction model 200 may be updated.

Accordingly, even when a real SEM image of a new pattern is input to the pre-trained contour extraction model 200, an accurate contour image may be extracted. That is, the present disclosure enables the pre-trained contour extraction model 200 to maintain high performance even under new semiconductor lithography patterns or changed conditions while maintaining existing learned information.

Hereinafter, descriptions of the same configurations among the configurations described above are omitted.

Referring again to FIG. 3, the contour extraction model learning method includes operation S110 of extracting a first contour image by inputting a SEM image of a new pattern to the contour extraction unit 210, operation S120 of generating a virtual SEM image by inputting the first contour image to the style transfer model 220, and operation S130 of training the contour extraction model 230 based on a training dataset in which the first contour image is matched with the virtual SEM image.

Operation S110 of extracting the first contour image may include an operation of obtaining a layout image 11 corresponding to a SEM image, an operation of separating between a pattern region and a non-pattern region in the layout image, an operation of extracting center coordinates of each pattern corresponding to the pattern region, an operation of determining a coordinate range within a preset number of pixels based on the center coordinates of each pattern in the SEM image 10 matched to the layout image 11 as contour extraction regions 101, 102, . . . , an operation of detect contours of patterns in the contour extraction regions 101, 102, . . . but stopping the contour detection when the detected contours are out of the contour extraction regions 101, 102, . . . or when the detected contours exceed sizes of the pattern regions, and an operation of merging contours 101-1, 102-1, . . . of the patterns in the SEM image 10 to generate a first contour image 201.

Operation S120 of generating a virtual SEM image may include an operation of identifying a binarized pixel value from an input first contour image, an operation of detecting a pattern region corresponding to the first pixel value and a non-pattern region corresponding to the second pixel value, and an operation of generating the virtual SEM image having the pattern region and the non-pattern region which are converted.

Operation S130 of training the contour extraction model 230 may include an operation of extracting a first feature of each pattern from the input virtual SEM image, an operation of extracting a second feature of each pattern from a layout image corresponding to the virtual SEM image, an operation of generating a third feature of each pattern by combining the first feature of the virtual SEM image with the second feature of the layout image, and an operation of generating a second contour image based on the third feature of each pattern.

In addition, the contour extraction model learning method may further include an operation of sharing the weights learned by the training dataset with the pre-trained contour extraction model 200.

A learning method according to an embodiment of the present disclosure may be performed in the form of a recording medium including instructions executable by a computer, such as a program module executed by a computer. A computer readable medium may be any available medium that may be accessed by a computer and includes both volatile and nonvolatile media, removable and non-removable media. Also, the computer readable medium may include a computer storage medium. A computer storage medium includes both volatile and nonvolatile media and removable and non-removable media implemented by any method or technology for storing information, such as computer readable instructions, data structures, program modules or other data.

Also, although the method and system of the present disclosure are described with respect to specific embodiments, some or all of components or operations thereof may be implemented by using a computer system having a general-purpose hardware architecture.

The description of the present disclosure made above is for illustrative purposes only, and those skilled in the art will appreciate that the present disclosure may be easily modified into other specific forms without changing the technical idea or essential characteristics of the present disclosure. Therefore, the embodiments described above should be understood as illustrative in all respects and not limiting. For example, the components described in a single type may also be implemented in a distributed manner, and likewise, the components described in the distributed manner may be implemented in a combined manner.

The scope of the present application is indicated by the claims described below rather than the detailed description above, and all changes or modified forms derived from the meaning, scope of the claims, and their equivalent concepts should be interpreted as being included in the scope of the present application.

What is claimed is:

1. A contour extraction model learning device for detecting a contour of a semiconductor lithography pattern, the contour extraction model learning device comprising:
a memory storing a contour extraction training program; and
a processor configured to execute the contour extraction training program stored in the memory,
wherein the contour extraction training program extracts a first contour image by inputting a SEM image of a new pattern to a contour extraction unit, generates a virtual SEM image by inputting the first contour image to a style transfer model, and trains the contour extraction model based on a training dataset in which the first contour image is matched with the virtual SEM image.

2. The contour extraction model learning device of claim 1, wherein the contour extraction unit
obtains a layout image corresponding to the SEM image,
separates between a pattern region and a non-pattern region in the layout image and extracts center coordinates of each pattern corresponding to the pattern region,
determines a coordinate range within a preset number of pixels based on the center coordinates of each pattern in the SEM image matched with the layout image as a contour extraction region,
detects a contour of a pattern in the contour extraction region, but stops detection of the contour when a detected contour of the pattern is out of the contour extraction region or exceeds a size of the pattern region, and
merges contours of patterns detected from the SEM image to generate the first contour image.

3. The contour extraction model learning device of claim 1, wherein
the style transfer model is a model pre-trained by using a training dataset including a contour image and a SEM image matched to the contour image, and
the style transfer model identifies a binarized pixel value in the first contour image which is input, detects a pattern region corresponding to a first pixel value and a non-pattern region corresponding to a second pixel value, and generates a virtual SEM image in which the pattern region and the non-pattern region are converted.

4. The contour extraction model learning device of claim 1, wherein
the contour extraction model is an auto-encoder model constructed based on the training dataset in which the first contour image matches the virtual SEM image, and
the contour extraction model includes an encoder that extracts a first feature of each pattern from the input virtual SEM image, and a decoder that extracts a second feature of each pattern from a layout image corresponding to the virtual SEM image, generates a third feature of each pattern by combining the first feature of the virtual SEM image with the second feature of the layout image, and generates a second contour image based on the third feature of each pattern.

5. The contour extraction model learning device of claim 1, wherein
the contour extraction training program shares a weight learned by the training dataset with the contour extraction model which is pre-trained.

6. A contour extraction model learning method for detecting a contour of a semiconductor lithography pattern performed by a learning device, the contour extraction model learning method comprising:
extracting a first contour image by inputting a SEM image of a new pattern to a contour extraction unit;
generating a virtual SEM image by inputting the first contour image to a style transfer model; and
training the contour extraction model based on a training dataset in which the first contour image is matched with the virtual SEM image.

7. The contour extraction model learning method of claim 6, wherein the extracting of the first contour image comprises:
obtaining a layout image corresponding to the SEM image;
separating between a pattern region and a non-pattern region in the layout image and extracting center coordinates of each pattern corresponding to the pattern region;
determining a coordinate range within a preset number of pixels based on the center coordinates of each pattern in the SEM image matched with the layout image as a contour extraction region;
detecting a contour of a pattern in the contour extraction region, but stopping detection of the contour when a detected contour of the pattern is out of the contour extraction region or exceeds a size of the pattern region; and
merging contours of patterns detected from the SEM image to generate the first contour image.

8. The contour extraction model learning method of claim 6, wherein the generating of the virtual SEM image comprises:
identifying a binarized pixel value in the first contour image which is input;
detecting a pattern region corresponding to a first pixel value and a non-pattern region corresponding to a second pixel value; and
generating a virtual SEM image in which the pattern region and the non-pattern region are converted.

9. The contour extraction model learning method of claim 6, wherein the training of the contour extraction model comprises:
extracting a first feature of each pattern from the input virtual SEM image;
extracting a second feature of each pattern from a layout image corresponding to the virtual SEM image;
generating a third feature of each pattern by combining the first feature of the virtual SEM image with the second feature of the layout image; and
generating a second contour image based on the third feature of each pattern.

10. The contour extraction model learning method of claim 6, further comprising:
sharing a weight learned by the training dataset with the contour extraction model which is pre-trained.

11. A non-transitory computer-readable recording medium in which a computer program for executing the contour extraction model learning method according to claim 6 is recorded.
